(19) United States
(12) Patent Application Publication
(10) Pub. No.: US 2008/0296050 A1
(43) Pub. Date: Dec. 4, 2008

(54) Semiconductor chip mounting board with multiple ports

(75) Inventors: Hisanori Uda, Nagoya (JP); Tetsuya Katayama, Aichi-ken (JP)

Correspondence Address: HARNESS, DICKEY & PIERCE, P.L.C., P.O. BOX 828, BLOOMFIELD HILLS, MI, 48303, US

(73) Assignee: DENSO CORPORATION, Kariya-city (JP)

(21) Appl. No.: 12/150,343

(22) Filed: Apr. 25, 2008

(30) Foreign Application Priority Data
Apr. 27, 2007 (JP) 2007-120041

(51) Int. Cl. H05K 1/03

(52) U.S. Cl. 174/255

(57) ABSTRACT

A semiconductor chip mounting board comprises an insulating substrate and a plurality of input or output ports to be connected to a semiconductor chip for processing a high-frequency signal. The semiconductor chip has on top thereof a chip ground layer structured by a metal layer. The insulating substrate comprises a strip line formed on top thereof and to be connected to the ports, and a cavity, or a recessed space, for embedding the semiconductor chip therein. The substrate further comprises a common ground made of metal and exposed to the bottom face of the cavity, a coplanar line connected to the strip line, triple parallel bonding wires connecting the connecting terminals of the chip and the coplanar line, and embedded conductors embedded at least in portions of an annular groove or annular gap defined between the inner wall surface of the cavity and the side faces of the chip.

### CROSS-REFERENCE TO RELATED APPLICATION

This application is based on and claims the benefit of priority from earlier Japanese Patent Application No. 2007-120041 filed Apr. 27, 2007, the description of which is incorporated herein by reference.

### BACKGROUND OF THE INVENTION

1. [Technical Field of the Invention]

The present invention relates to a semiconductor chip mounting board with multiple ports, on which a semiconductor chip for processing high-frequency signals is mounted.

2. [Background Art]

Semiconductor chip mounting boards with multiple ports are known, in which a recessed space is formed in a top face of an insulating substrate to embed a semiconductor chip therein. Such a type of mounting board is disclosed, for example, in Japanese Patent Laid-Open Publication Nos. 2001-094012 and 2001-102820. A semiconductor chip is embedded in the recessed space so that, for example, bonding wires can be shortened, and the size of the mounting board can be reduced.

In such a semiconductor chip mounting board, serially joined and integrated conductors serve both as a rear face ground of a semiconductor chip and as a ground (hereinafter referred to as a “common ground”) to be formed under (back side of) a strip line or a coplanar line. The coplanar line and the semiconductor chip are connected through triple parallel bonding wires. The center line of the triple parallel bonding wires serves as a signal line, and the lateral side bonding wires, or the ground lines, are connected to a metal layer (chip ground layer) formed on top of the semiconductor chip. An annular groove making a circuit of the semiconductor chip is formed immediately under the triple parallel bonding wires, with the common ground being exposed to a bottom face of the groove.

In particular, for example, recent mounting boards, such as for a millimeter wave SiGe IC, cause large loss when a high-frequency electromagnetic field enters the semiconductor substrate. Therefore, a multilayer structure has been in heavy usage. The multilayer structure is formed by stacking a chip ground layer (metal layer) on a semiconductor substrate of the millimeter wave IC, stacking thereon an insulating layer, and further arranging thereon a signal line (strip conductor). By introducing such a multilayer structure, a high-frequency signal propagates between the strip conductor and the chip ground layer. Thus, entry of unnecessary electromagnetic field into the semiconductor substrate can be effectively prevented by the chip ground layer.

Use of the coplanar line and the triple parallel bonding wires in the semiconductor chip mounting board as described above is purposed to achieve good impedance matching.

However, introducing the multilayer structure as described above may not only allow the high-frequency signal to propagate between the strip conductor and the chip ground layer, but also allow the high-frequency signal to partially propagate between the common ground on the rear face of the semiconductor chip and the chip ground layer. Therefore, a parallel plate mode is excited between the chip ground layer and the common ground. As a result, isolation between the multiple ports is deteriorated. The mechanism of excitation of the parallel plate mode is described below.

All of the lines of electric force from the signal line do not necessarily reach the bonding wires on the lateral sides (ground lines), but may also reach the common ground immediately under the ground lines. Specifically, high frequency leaks out a little from the signal line and reaches the common ground. This leakage of the lines of electric force may allow the ground lines to have potential for the common ground. Thus, the chip ground layer directly connected to the ground lines may resultantly have potential for the common ground. As a result, a common mode is caused at the chip ground layer to excite the parallel plate mode mentioned above. The excitation is likely to concentrate on the edges of parallel plates, so that the excitation (exciting electric field) propagates around the semiconductor chip along the annular groove mentioned above. The tendency for the electric field to concentrate on the edges of the chip ground layer is caused by the same mechanism as the mechanism that electric field is likely to concentrate on the edges of generally used strip conductors (signal lines).

In this way, high-frequency energy that has been caused by the excitation leaks into other ports to deteriorate isolation between the multiple parts.

### SUMMARY OF THE INVENTION

The present invention has been made to solve the problem described above, and has as its object to enhance isolation between multiple ports (hereinafter referred to as “inter-port isolation”) of a semiconductor chip mounting board in which a semiconductor chip is embedded.

The following aspects may be effective for solving the problem described above.

Specifically, a first aspect of the present invention comprises: a plurality of input or output ports to be connected to a semiconductor chip for processing a high-frequency signal, the semiconductor chip having connecting terminals and side faces and having on top thereof a chip ground layer structured by a metal layer; and an insulating substrate comprises: a strip line formed on top of the insulating substrate and to be connected to the ports; a cavity having a bottom face and an inner wall surface, or a recessed space with its upper end being open, for embedding the semiconductor chip therein; a common ground made of metal and exposed to the bottom face of the cavity; a coplanar line connected to the strip line; triple parallel bonding wires connecting the connecting terminals of the semiconductor chip and the s coplanar line; and embedded conductors which are embedded at least in portions of an annular groove or annular gap defined between the inner wall surface of the cavity and the side faces of the semiconductor chip.

The connecting terminals are provided by three per port. Two lateral terminals among the three are connected to the chip ground layer. Two lateral bonding wires (ground lines) of the three parallel bonding wires are connected to the lateral connecting terminals, respectively, connected to the chip ground layer. The common ground may be made up of composite conductors serially formed through a number of via holes, for example, which are formed on a dielectric is substrate, for example.

The chip ground layer may be formed on top of the semiconductor chip, or at an upper layer portion other than the uppermost layer of the semiconductor chip. Accordingly, top of the chip ground layer may be covered with resin, for example.

The specific structure or application of the semiconductor chip may be optionally selected. The three-dimensional shape may also be optionally selected, and thus may not necessarily be substantially a rectangular parallelpiped.

In a second aspect of the present invention according to the first aspect, the embedded conductors are formed, being in non-contact with the chip ground layer.

In a third aspect of the present invention, the embedded conductors each have a columnar shape, stand on the common ground, have a head portion which is at substantially the same level as that of the chip ground layer, and are periodically arranged along the annular groove at a period ranging from 0.35 or more times to 0.70 or less times of the wavelength of a target high frequency annularly propagating through the annular groove.

However, the period of arrangement may most preferably be one half of the wavelength (guide wavelength) with which the target high frequency annularly propagates.

In a fourth aspect of the present invention, according to any one of the first to third aspect, the semiconductor chip has a rectangular shape in plan; and

the embedded conductors each have a columnar shape, stand on the common ground, have a head portion which is at substantially the same level as that of the chip ground layer, and are arranged at least at four corners of the annular groove or in the vicinities of the four corners.

However, when the shape of the semiconductor chip in plan is square, the embedded conductors may preferably be arranged at least at four corners of the annular groove.

In a fifth aspect of the present invention, according to any one of the first to fourth aspect, the semiconductor chip has a square shape in plan; and one side of the square shape has a length which is an integral multiple of one half of the wavelength of the target high frequency annularly propagating through the annular groove.

In a sixth aspect of the present invention, according to any one of the first to fifth aspect, the insulating substrate has a waveguide inside the wall surface of the cavity, the waveguide being made of a conductor and continuously provided circuiting along the wall surface.

A seventh aspect of the present invention, according to any one of the first to sixth aspect, the strip line is structured by a first signal strip conductor having an extended end portion, and formed on top of a dielectric substrate structuring the upper part of the insulating substrate; the dielectric substrate has a ground conductor having a certain width and disposed under the first signal strip conductor, being stacked onto the rear face of the dielectric substrate; the coplanar line comprises: a second signal strip conductor which is formed on top of the dielectric substrate and connected to the first signal strip conductor, without being provided with the ground conductor immediately thereunder; a pair of first ground strip conductors which are parallelly formed on the rear face of the dielectric substrate, being extended from the ground conductor so as to be located obliquely lateral sides of the extended end portion of the first signal strip conductor, or obliquely lateral sides of the second signal strip conductor; and a pair of second ground strip conductors which are formed on the top of the dielectric substrate so as to be located obliquely lateral sides of the second signal strip conductor, and are connected to the pair of first ground strip conductors, respectively, through via holes formed in the dielectric substrate.

Hereinafter, the direction perpendicular to a top face of the dielectric substrate is referred to as a “vertical” or “up-and-down” direction. The longitudinal direction of the first signal strip conductor is referred to as a “front-back” direction. A direction perpendicular to both of the above directions is referred to as a “lateral” direction.

The term “extended end portion” refers to an end portion of the first signal strip conductor facing the semiconductor chip. The extended end portion may be structured, for example, by a bonding wire connecting the first and second signal strip conductors. The ground conductor having a certain width may preferably not formed under the extended end portion.

In an eighth aspect of the present invention according to any one of the first to seventh aspect, the target high frequency is a millimeter wave; and the semiconductor chip has an integrated circuit for processing the millimeter wave. The problem described above can be effectively or reasonably solved using the aspect of the present invention described above.

As described above, the distribution of the electric field of the chip ground layer, which is excited by a common mode (parallel plate mode), is likely to be concentrated on the edges of the metal layer and the vicinity thereof. Accordingly, the common mode can be effectively suppressed by taking a measure for preventing propagation of high frequency, with respect to the annular groove between the semiconductor chip and the substrate.

Specifically, according to the first aspect of the present invention, the excitation of high frequency that propagates along the annular groove can be effectively suppressed, the excitation having been caused by the excitation of the parallel plate mode that occurs between the chip ground layer and the common ground. This is because the embedded conductors can serve as barriers, forming a filter for preventing annular propagation of the electromagnetic field. For example, it is known that, when propagation barriers made, for example, of metal are established at a half-wave period, being perpendicular to the traveling direction of the electromagnetic field, the periodic structure can prevent the traveling of the electromagnetic field to deteriorate the electromagnetic field. Japanese Patent No. 3589137, for example, discloses quite simple examples of this technique.

Thus, according to the first aspect of the present invention, the excitation energy stored in the annular groove can be effectively prevented from being increased caused by the parallel plate mode. As a result, the inter-port isolation can be effectively enhanced.

In order to suppress the excitation of the parallel plate mode, an approach, for example, may be made for connecting both of the plates (the chip ground layer and the common ground) using a plurality of bonding wires, for example, to keep the potentials of both of the plates at substantially the same level. However, in the case of using bonding wires, inductor components are permitted to be contained in the conductors, which may cause difficulty in lowering the value to about 50 pH or less. In this case, therefore, it is not necessarily easy to keep the potentials of both of the plates at substantially the same level.

In addition, in order to arrange such bonding wires, ground pads have to be provided on the common ground around the semiconductor chip. However, providing such a space for arranging the pads may lead to the increase in the size of the cavity, giving adverse factors for desirably reducing the size of the semiconductor chip mounting board.

However, since the advantages of the present invention may be brought about by the filtering effect associated with the annular propagation of the electric field, the embedded conductors may not be required to be connected to the chip ground layer.

Thus, according to the second aspect of the present invention for allowing the embedded conductors to be in non-contact with the chip ground layer, the embedded conductors can be quite readily arranged, irrespective, for example, of the specific structure (specification) of the semiconductor as chip described above. Thus, according to the second aspect of the present invention, the manufacturing cost of the inventive semiconductor chip mounting board can be effectively suppressed, irrespective of the specific structure of the semiconductor chip.

According to the third aspect of the present invention, the embedded conductors can be arranged at a half-wave period of the target high frequency (half of guide wavelength) or the period near this length. This periodic structure may allow the filtering effect to effectively appear, for the high frequency that annularly propagates through the annular groove.

It is empirically known that use of the forth aspect of the present invention can more effectively suppress the excitation of the annularly propagating high frequency, than in the case where each embedded conductor is arranged near the center of each side. This is because it is assumed that electric field is likely to concentrate on the corners of the chip ground layer, i.e. the four corners of the annular groove, however, no detailed mechanism is known.

When the semiconductor chip to be mounted is formed into a rectangular shape in plan, connecting terminals or high-frequency circuits are hardly arranged in the vicinities of the four corners. In this regard, the fourth aspect of the present invention can cast aside the concern that the embedded conductors may accidentally give adverse effects to the circuit operation in a semiconductor chip of a widely and generally used specification. Examples of such adverse effects may include deterioration of impedance matching with a semiconductor chip circuit, and accidental contact (short circuit) of the embedded conductors with signal lines, connecting terminals or the like.

Generally, the annular groove is formed to have a very narrow width because of downsizing. Therefore, embedding the embedded conductors in the annular groove is not necessarily easy. However, in case of forming a recessed space having a rectangular shape in plan and through holes in a plate, each of the four corners of the rectangle, in general, is formed into a rounded arc shape, being slightly projected outward with a center angle of about 180°. Accordingly, a little spatial room is produced in the horizontal direction (outward in the direction of the width of the annular groove) around each of the corners of the rectangle (annular groove).

Thus, utilizing the rooms, each having an inner peripheral wall surface of an arc shape in plan, which are formed at the four corners of the recessed space (annular groove), the embedded conductors can be quite easily arranged at the respective four corners. Methods for obtaining such an arrangement may include one for simply embedding a metal paste, for example, at the respective four corners.

Thus, according to the fourth aspect of the present invention, the increase in the manufacturing cost of the desired semiconductor chip mounting board can be effectively suppressed.

The slightly projected arc-shaped rooms are outwardly formed at the four corners of the recessed space (annular groove) through the machining processes as explained below. Specifically, for example, in the normal processing of substrates, a substantially columnar elongated grinding tool or polishing tool, such as a drill, is used to form each side of the rectangle with high accuracy. Unless the projected rooms are formed, a rounding having a radius of the tool has to be formed inside of each of the corners of the rectangle.

Forming roundings inside the four corners of the rectangle defining the recessed space is unpopular because such inside roundings may not allow the rectangular semiconductor chip having substantially the same size as the recessed space to be located (stored) in the recessed space. As a matter of course, a lower value is set for the radius of the elongated column of a tool which requires sufficient durability. Therefore, unless a special or costly substrate processing is carried out, the spatial rooms as mentioned above are necessarily formed at four corners of the annular groove.

The fifth aspect of the present invention enables simultaneous execution of the third and fourth aspect of the present invention to most effectively arrange the embedded conductors.

According to the sixth aspect of the present invention, the electric field propagating through the annular groove can be effectively prevented from leaking therearound. Thus, in combination of this sixth aspect with any one of the aspect described above, the inter-port isolation may be more effectively enhanced. The arrangement of the waveguide described above may contribute to exerting constant effect in further reducing the amount of reflection of the input power from an input port, and in further broadening the bandwidth for the inter-port isolation.

According to the seventh aspect of the present invention, a dielectric substrate is interposed between the second signal strip conductor and the first ground strip conductor to impart a two-layer structure to the coplanar line. This may realize a transmission mode which is intermediate between a transmission mode by a microstrip line and a transmission mode by the conventional coplanar line. Thus, according to the seventh aspect of the present invention, the transmission mode can be gradually changed, and power loss accompanying the mode change can be effectively reduced.

The eighth aspect of the present invention can increase the size of the gap between a signal line and a ground line, e.g. about 100 μm. This may eliminate the particularly fine processing that has been used for the processing of ceramics, from the manufacturing processes of the configuration described above. Thus, according to the eighth aspect of the present invention, an organic substrate can be used for the dielectric substrate, whereby a desired insulating substrate (semiconductor chip mounting board) can be formed at lower cost than in the conventional manufacture.

For example, a mounting board for a semiconductor chip (integrated circuit), such as a mounting board for an RF switch useful for a millimeter wave radar, very often has three or more I/O ports. In this technical field, ensuring high-frequency isolation between multiple ports has been a big issue. This is because, in this technical field, in particular, a plane (side) having an I/O port for high-frequency signals very often has another adjacently located port, or a plane (side) adjacent to a plane having an I/O port for high-frequency signals very often has another adjacently located port.

Thus, the eighth aspect of the present invention is very useful, in particular, for reducing the size of the mounting board to mount thereon a substrate of an integrated circuit that processes millimeter waves, and for ensuring inter-port isolation.

It is preferred that the line lengths of the first and second ground strip conductors are determined so that, in a desired frequency, the lateral ground lines in the triple parallel bonding wires and the chip ground layer are short-circuited at a connecting point. For example, the length of the short circuit path from the connecting point to the common ground may be determined so as to have a half of the target high-frequency wavelength (electrical length or guide wavelength). This may allow the impedance level at the connecting point to be the same as that of the common ground. Briefly, the connecting point can be substantially short-circuited.

Thus, by connecting, for example, the coplanar line and the semiconductor chip, the chip ground layer of the semiconductor chip may be substantially grounded at a desired frequency. In this way, the occurrence of the common mode that should be suppressed by the operation based on the aspect of the present invention, can be minimized in advance.

### BRIEF DESCRIPTION OF THE DRAWINGS

In the accompanying drawings:

FIG. 1 is a perspective view illustrating a semiconductor chip mounting board according to a first embodiment of the present invention;

FIG. 2 is a cross sectional view illustrating a semiconductor chip to be mounted on the semiconductor chip mounting board according to the first embodiment;

FIG. 3 is a perspective view of a coplanar line and a vicinity thereof in the semiconductor chip mounting board according to the first embodiment;

FIG. 4 is a cross sectional view taken along a line E-E′ of FIG. 3;

FIG. 5A is a cross sectional view taken along a line A-A′ shown in FIGS. 3 and 4;

FIG. 5B is a cross sectional view taken along a line B-B′ shown in FIGS. 3 and 4;

FIG. 5C is a cross sectional view taken along a line C-C′ shown in FIGS. 3 and 4;

FIG. 5D is a cross sectional view taken along a line D-D′ shown in FIGS. 3 and 4;

FIG. 6 is a graph illustrating the results of evaluation on isolation in the semiconductor chip mounting board according to the first embodiment;

FIG. 7 is a graph illustrating the results of evaluation on isolation of Comparative Example 1 with respect to the first embodiment;

FIG. 8 is a perspective view illustrating a semiconductor chip mounting board according to a second embodiment of the present invention;

FIG. 9 is a graph illustrating the results of evaluation on isolation in the semiconductor chip mounting board according to the second embodiment;

FIG. 10 is a graph illustrating the results of evaluation on isolation of Comparative Example 2 with respect to the second embodiment; and

FIG. 11 is a plan view illustrating an outline of an annular groove according to a third embodiment of the present invention.

### DETAILED DESCRIPTION OF THE PREFERRED EMBODIMENTS

With reference to the accompanying drawings, hereinafter will be described in detail some embodiments of the present invention.

It should be appreciated that the present invention is not intended to be limited to the embodiments described below. It should also be appreciated that, throughout the embodiments, the identical or similar components or portions are given the same reference numerals for the sake of omitting explanation.

### First Embodiment

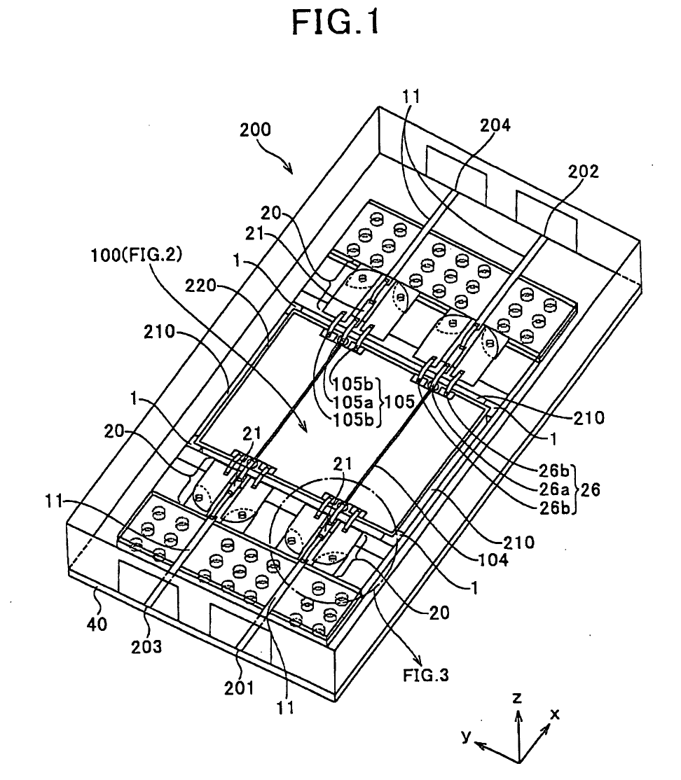

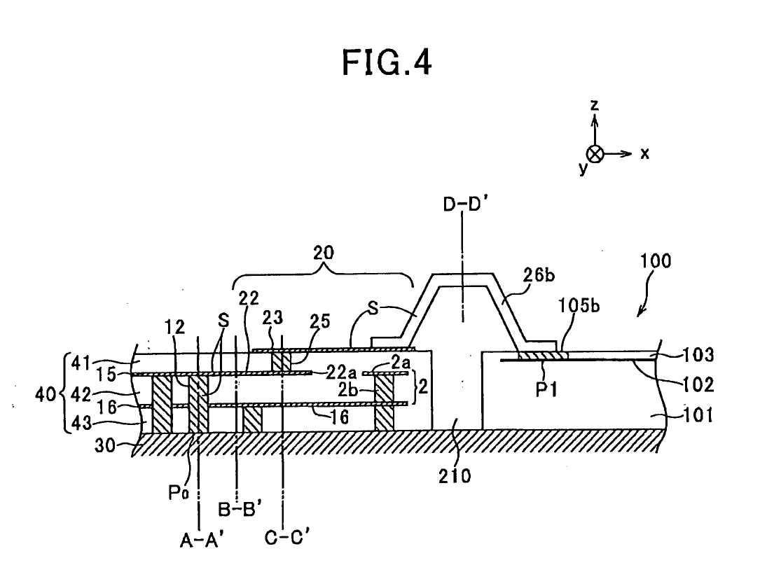

FIG. 1 is a perspective view illustrating a semiconductor chip mounting board 200 according to a first embodiment of the invention, which is provided with four input-output (I/O) ports. The semiconductor chip mounting board 200 has a recessed space on top of an insulating substrate 40, with an upper face of the space being open. The recessed space forms a cavity 220 which is substantially rectangular parallelpiped and has a squared configuration in plan. A semiconductor chip 100 is mounted in the cavity 220. The semiconductor chip mounting board 200 is provided with a total of four I/O ports 201, 202, 203 and 204 as well as connecting terminals 105 disposed at a total of four positions in the semiconductor chip 100. Each of the connecting terminals 105 is connected to any one of the I/O ports (201, 202, 203 and 204) via, for example: a coplanar line 20 having a second signal strip conductor 21; a first signal strip conductor 11 formed on top of an uppermost layer (see dielectric substrate 41 of FIG. 4) among a plurality of dielectric substrates configuring the insulating substrate 40; and triple parallel bonding wires 26.

Hereinafter, the longitudinal direction of the first signal strip conductor 11 is referred to as an “x-axis direction”, the direction perpendicular to the top face of the insulating substrate 40 is referred to as a “vertical direction” or a “z-axis direction”, and the direction perpendicular to the x- and z-axis directions is referred to as a “lateral direction”, “left-and-right direction” or “y-axis direction”. The semiconductor chip mounting board 200 including the semiconductor chip 100 is formed so as to be symmetric to both the x-axis and the y-axis.

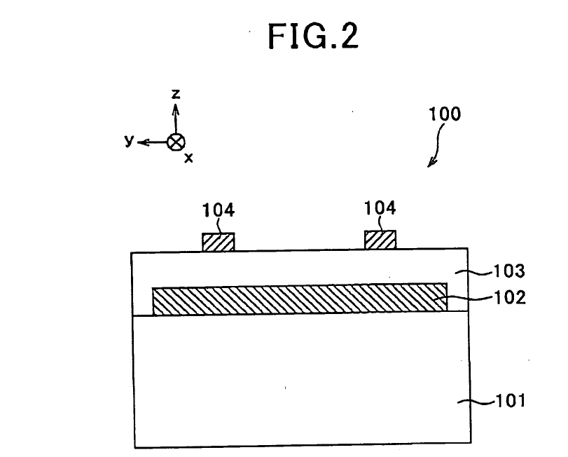

FIG. 2 shows a cross-sectional view illustrating the semiconductor chip 100 to be mounted on the semiconductor chip mounting board 200. The semiconductor chip 100 is a dummy chip for running a test (simulation test) on the operation (high-frequency propagation characteristics) of the semiconductor chip mounting board 200. The semiconductor chip 100 is stacked, on top of a silicon substrate 101, with a chip ground layer 102 made of gold (Au), which is further stacked, on top thereof, with an SiO₂ layer 103. Also, two signal lines 104 made of gold (Au) are formed on top of the SiO₂ layer 103, being parallel to each other in longitudinal (x-axis) direction in stripes. In the semiconductor chip mounting board 200, a switch or a semiconductor IC circuit for processing millimeter waves, for example, are normally arranged in the silicon substrate 101 instead of the signal lines 104. However, herein, such a dummy chip is arranged to check standard operations, such as inter-port isolation, in the semiconductor chip mounting board 200.

As shown in FIG. 1, the semiconductor chip 100 is substantially rectangular parallelpiped, with its side length in longitudinal (x-axis) and lateral (y-axis) direction being about 2.5 mm. This length corresponds to approximately one half (approximately 63%) of the annularly directed wavelength of a target high frequency (76.5 GHz) in an annular groove 210 in the first embodiment.

As shown in FIG. 1, the annular groove 210, whose outline is substantially square ring shaped in plan, is defined around the semiconductor chip 100. The groove 210 corresponds to a space that has remained after locating the semiconductor chip 100 in the cavity 220. A columnar conductor 1 made of silver paste is embedded in each of four corners of the annular groove 210. The columnar conductors 1 correspond to the “embedded conductors” of the present invention. Specifically, the columnar conductor 1 is arranged at each of the four corners of the annular groove 210, a gap defined by an inner wall surface of the cavity 220 and a side wall surface of the semiconductor chip 100. Each of the columnar conductors 1 directly stands on a common ground 30 (see FIG. 4) arranged on a rear face of the is semiconductor chip 100. A head portion (top face) of each columnar conductor 1 is substantially at the same level as that of the chip ground layer 102.

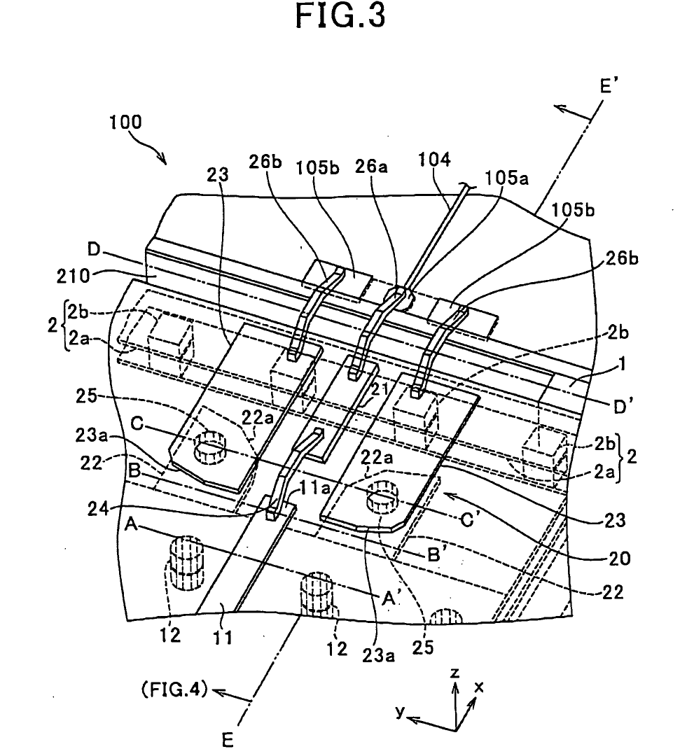

FIG. 3 is a perspective view including the coplanar line 20 and the vicinity thereof of the semiconductor chip mounting board 200. No SiO₂ layer 103 is formed immediately under two connecting terminals 105b shown in FIG. 3. As shown in FIG. 4, the two connecting terminals 105b of FIG. 3 are directly connected to the chip ground layer 102 through respective conductive holes formed in the SiO₂ layer 103. As shown in FIG. 3, a connecting terminal 105a arranged between the two connecting terminals 105b is formed over the SiO₂ layer 103 and one end of the signal line 104.

Particularly, the connecting terminal 105a shown in FIG. 3 serves as an input terminal for inputting high frequency (input signal) into the semiconductor chip 100 from the input port 201 shown in FIG. 1. A signal line connecting the input port 201 and the connecting terminal 105a is formed by sequentially connecting in series the first signal strip conductor 11, a bonding wire 24, the second signal strip conductor 21 and a bonding wire 26a.

In this case, impedance matching can be adjusted between the first and second signal strip conductors 11 and 21 by using the bonding wire 24 for connection. The first and the second signal strip conductors 11 and 21 are formed on the plane of the same dielectric substrate (dielectric substrate 41 of FIG. 41). A pair of band-like second ground strip conductors 23 is provided on the lateral sides of the second signal strip conductor 21, extending in the longitudinal (x-axis) direction on the same plane and each being spaced apart from the second signal strip conductor 21 by about 100 μm. However, no metal layer (ground conductor 15 of FIG. 4), which constitutes a ground for the first signal strip conductor 11, is arranged immediately under the second signal strip conductor 21. In other words, a layer of the ground conductor 15 having a large width is stacked on a rear face of the dielectric substrate 41 under the first signal strip conductor 11. This metal layer is stacked covering a wide lateral range, but is not located immediately under the second signal strip conductor 21.

FIG. 4 shows a cross sectional view taken along a line E-E′ of FIG. 3. As can be seen from FIG. 4, on the rear face of the dielectric substrate 41, a pair of belt-like first ground strip conductors 22, which are parallel to each other, is formed being extended and projected in the x-axis direction from portions of the ground conductor 15 which portions correspond to obliquely lateral side portions of the ground conductor 15 near an extended end portion 11a of the first signal strip conductor 11. The pair of first ground strip conductors 22 is connected to the pair of second ground strip conductors 23 mentioned above, respectively, through respective via holes 25 formed in the dielectric substrate 41.

As described above, the coplanar line 20 of the semiconductor chip mounting board 200 is configured by the second signal strip conductor 21, the pair of first ground strip conductors 22, the pair of second ground strip conductors 23, the bonding wire 24 and the two via holes 25.

The insulating substrate 40 shown in FIG. 4 includes: three layers of dielectric substrates 41, 42 and 43; metal layers 15 and 16 partially stacked between the dielectric substrate layers; and a number of via holes.

A short-circuit path S is provided extending from a connecting point P₁ between the connecting terminal 105b and the chip ground layer 102, through a via hole 25, to a connecting point P₀ between a via hole 12 and the common ground 30. In order to short-circuit the potential of the chip ground layer 102, the length of the short-circuit path S is set one half of the target high frequency wavelength (electrical length) propagating this path. By this setting, the potential of the chip ground layer 102 can substantially be short-circuited for the common ground 30 at the target frequency.

As shown in FIGS. 3 and 4, a waveguide 2 is formed making a circuit along and enclosing the annular groove 210. The waveguide 2 is structured by a guide plate 2a and support columns 2b supporting the guide plate 2a, both of which are made of a metal conductor. On the rear face of the dielectric substrate 41, the guide plate 2a is continuously and annularly formed making a circuit around the annular groove 210. The support columns 2b are allowed to stand on the metal layer 16, with an interval therebetween in the annular direction. The interval is set sufficiently small for the wavelength of the high frequency that annularly propagates through the annular groove 210. The metal layer 16 is provided for the purpose of steadying the potential of the ground conductor 15, and constantly has substantially the same potential as that of the common ground 30. The waveguide 2 plays a roll of guiding the high frequency that annularly propagates through the annular groove 210, permitting the high frequency to stay within the groove. Thus, the waveguide 2 prevents the high frequency from propagating through the insulating substrate 40.

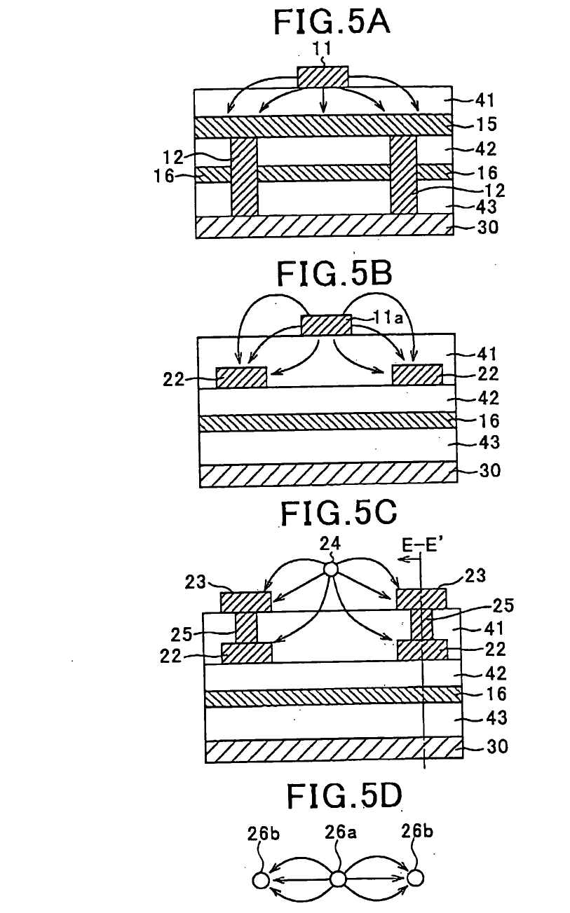

FIGS. 5A to 5D illustrate cross-sectional views (taken along lines A-A′, B-B′, C-C′ and D-D′, respectively, of FIG. 4), which are perpendicular to the longitudinal (x-axis) direction of FIGS. 3 and 4. FIG. 5A illustrates directions of electric field in a transmission mode of a microstrip line, provided by the first signal strip conductor 11. FIG. 5B is a cross-sectional view including the extended end portion 11a of the first signal strip conductor 11. The pair of first ground strip conductors 22 in this figure can be regarded as a ground for the coplanar line, with its height being slightly lowered and offset from the extended end portion 11a.

FIG. 5C is a cross-sectional view including the bonding wire 24 and the via holes 25. The bonding wire 24 in this figure can be regarded as a signal line for the coplanar line, with its height being slightly made higher and offset from the pair of second ground strip conductors 23. In this figure, the ground for the coplanar line can be regarded as being thickly distributed substantially in vertical direction, resulting from the connection between the pair of first ground strip conductors 22 and the pair of second ground strip conductors 23 through the two via holes 25.

In this way, the cross-sectional views of FIGS. 5B and 5C show that progressive and stepwise realization may be enabled in an intermediate transmission mode between a transmission mode provided by the strip line and the transmission mode provided by the coplanar line. Owing to this, the directions of the electric field at the individual portions of the coplanar line 20 are gradually changed along the longitudinal (x-axis) direction. According to this configuration, the transmission modes can be naturally, gradually and successively switched, whereby reflection and leakage of the high frequency on the coplanar line 20 including the vicinity thereof can be effectively suppressed.

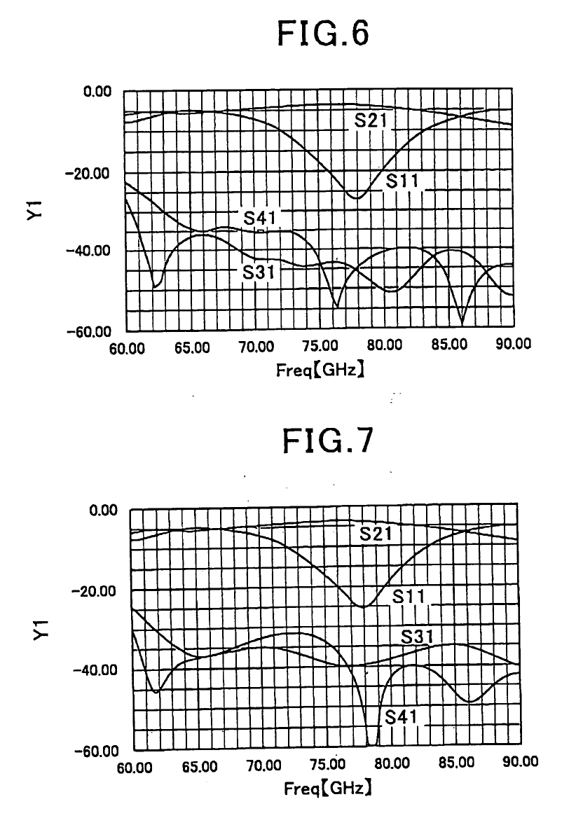

FIG. 6 shows the results of measurements obtained from a simulation test on the isolation characteristics of the semiconductor chip mounting board 200 according to the first embodiment. FIG. 7 shows isolation characteristics of Comparative Example 1 having completely the same structure as the semiconductor chip mounting board 200, except for the absence of the columnar conductors 1. Transmission, leakage or reflection for the individual ports was measured in these simulations by inputting high frequency of 76.5 GHz into the input port 201.

Specifically, in these graphs, indicated by 511 is an amount of reflection to the input port 201 for the input mentioned above, by S21 is an amount of transmission of the high frequency to the output port 202, and by S31 and S41 are leakage of the high frequency to the I/O ports 203 and 204.

As can be seen from the results of the simulations, when the embedded conductors (columnar conductors 1) are introduced based on the present invention, leakage of the high frequency to the adjacent ports (I/O ports 203 and 204) can be suppressed to −40.0 dBm or less in a broad bandwidth ranging from 74.5 GHz to more than 90.0 GHZ. In this way, the high-level isolation characteristics covering a broad bandwidth are difficult to obtain in a device (Comparative Example 1 of FIG. 7) without having the embedded conductors (columnar conductors 1).

Achievement of such an effect can be ascribed to the fact that the excitation of the high frequency annularly propagating through the annular groove 210 is blocked by the periodic arrangement of the columnar conductors 1. Specifically, approximately a half-wave period annular arrangement of the columnar conductors 1 can be considered to have effectively appeared as filtering effect of preventing the high frequency (from 74.5 GHz to more than 90.0 GHz) from annularly propagating through the annular groove 210.

### Second Embodiment

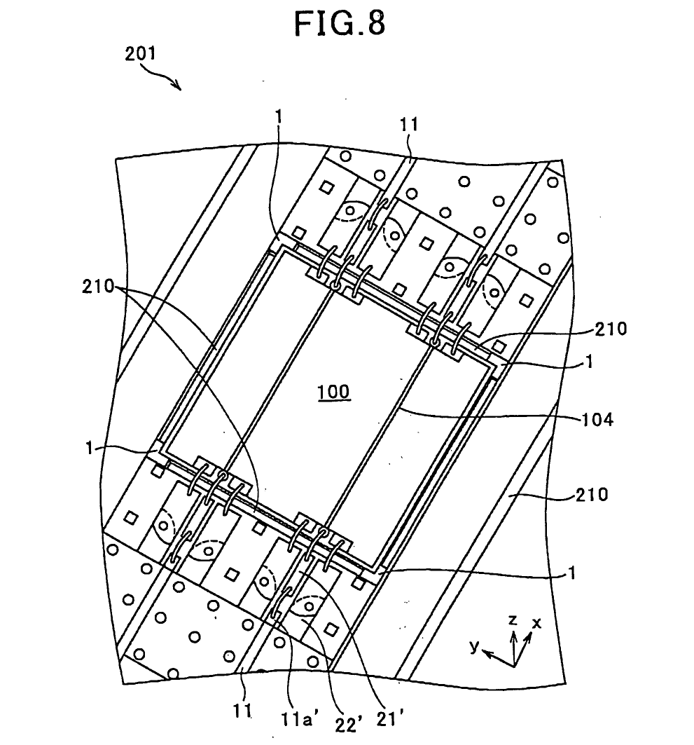

FIG. 8 is a perspective view illustrating a semiconductor chip mounting board 201 according to a second embodiment of the present invention.

The semiconductor chip mounting board 201 has been obtained by removing the waveguide 2 circling the annular groove 210, from the semiconductor mounting board 200 of the first embodiment. With this change, the impedance matching has been readjusted in the coplanar line 20. In other words, with the removal of the waveguide 2, lengths have been made larger in the longitudinal (x-axis) direction in respect of an extended end portion 11a′ of the band-like first signal strip conductor 11, a second signal strip conductor 21′, and a pair of first ground strip conductors 22′, than the corresponding components (11a, 21 and 22) in the semiconductor chip mounting board 200. In other words, these increased lengths result from the absence of the waveguide 2, which influences the matching of the coplanar line 20. The remaining structure is the same between the semiconductor chip mounting boards 200 and 201.

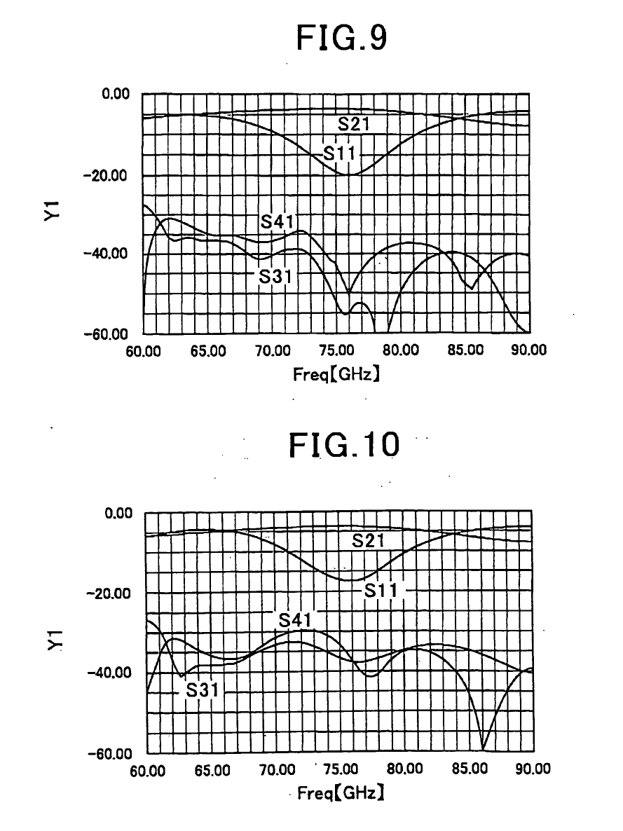

FIG. 9 illustrates the results of evaluation on the isolation characteristics of the semiconductor chip mounting board 201. As can be seen from the comparison of this graph with that of FIG. 6, significantly broader bandwidth can be achieved in the semiconductor chip mounting board 200 having the waveguide 2, regarding the frequency band in which leakage of the high frequency to the adjacent ports (I/O ports 203 and 204) is suppressed to −40.0 dBm or less.

Meanwhile, FIG. 10 illustrates the isolation characteristics of Comparative Example 2 having completely the same structure as the semiconductor chip mounting board 201, except for the absence of the columnar conductors 1.

As can be seen from the results of the simulations, when the embedded conductors (columnar conductors 1) are introduced based on the present invention, leakage of the high frequency to the adjacent ports (I/O ports 203 and 204) can be suppressed to −37.0 dBm or less in a broad bandwidth ranging from 73.5 GHz to more than 90.0 GHz. In this way, the high-level isolation characteristics covering a broad bandwidth are difficult to obtain in a device (Comparative Example 2 of FIG. 10) without having the embedded conductors (columnar conductors 1).

Also, as can be seen from the results of the simulations, or from the comparison between FIGS. 6 and 9 and between FIGS. 7 and 10, use of the waveguide 2 is considered to exert an effect of reducing the amount of reflection of the input signal for the input port 201, and of r increasing bandwidth which is associated with reducing the leakage of the high frequency to the adjacent ports (I/O ports 203 and 204).

### Third Embodiment

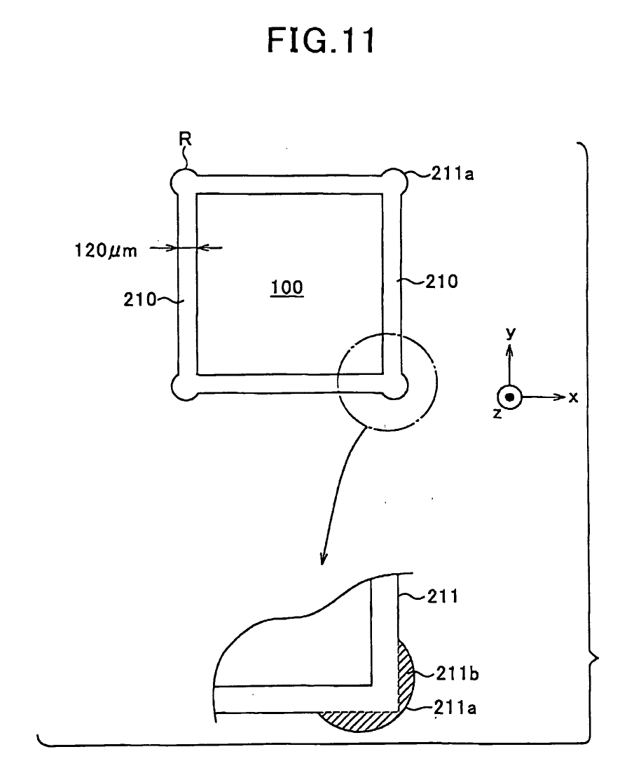

FIG. 11 illustrates another outline 211 of the annular groove 210 according to a third embodiment of the present invention. The outlines of the annular groove 210 in plan in the embodiments described above are the outlines in the simulations. When a recessed space having a rectangular shape in plan and having through holes are actually formed in a plate, four corners 211a of the rectangle (rectangle 211 (outline of the annular groove 210)) are generally rounded, being slightly projected outward, so as to have an arc shape with a center angle of about 180°. Accordingly, each of the corners of the rectangle 211 will have a little spatial room 211b therearound in the horizontal direction (outwardly crosswise direction of the annular groove 210).

Thus, utilizing the room 211b formed at each of the four corners of the recessed space (annular groove 210) and having an arc shape (211a) in plan, in its inner wall, the embedded conductors (columnar conductors 1) can be very easily located at the four corners. One method of locating the columnar conductors may only be carried out by simply embedding a metal paste, for example, at the individual four corners.

Such a method can effectively suppress the cost increase in the manufacture of desired semiconductor chip mounting boards (200, 201). In other words, according to a fourth embodiment of the present embodiment, the room 211b can be utilized to effectively reduce the manufacturing cost.

The slightly projected arc-shaped rooms 211b are outwardly formed at the four corners of the recessed space (annular groove 210) through the machining processes as explained below. Specifically, for example, in the normal processing of substrates, a substantially columnar elongated grinding tool or polishing tool, such as a drill, is used to form each side of the rectangle 211 with high accuracy. Unless the projected rooms 211b are formed, a rounding having a radius of the tool has to be formed inside of each of the corners of the rectangle 211.

Forming roundings inside the four corners of the rectangle 211 defining the recessed space is unpopular because such inside roundings may not allow the rectangular semiconductor chip 100 having substantially the same size as the recessed space to be located (stored) in the recessed space. As a matter of course, a lower value is set for the radius of the elongated column of a tool which requires sufficient durability. Therefore, unless a special or costly substrate processing is carried out, the spatial rooms 211b as mentioned above are necessarily formed at four corners of the annular groove 210.

### MODIFICATIONS

The embodiments of the present invention are not limited to the ones described above, but may be modified as exemplified below. The advantages of the present invention may also be enjoyed by such modifications and applications.

### Modification 1

The guide plate 2a has been horizontally stacked in the first embodiment. Alternative to this, the guide plate 2a of the waveguide 2 may be vertically provided.

Further, the I/O ports 201 to 204 have been provided at the front and the rear of the semiconductor chip 100. The number of the I/O ports of the semiconductor chip mounting board of the present invention may be optional, and the positions of these I/O ports may also be optional and thus may be provided, for example, at the front, rear, left and right.

The present invention may be advantageous when used as a substrate for mounting a high-frequency semiconductor chip, and in particular, as a mounting board, for example, for a semiconductor chip having a millimeter wave processing circuit having a ground in the vicinity of the surface. Thus, the mounting board of the present invention is excellent or most suitable for mounting boards for semiconductor chips (e.g., RF switch) having an integrated circuit for millimeter wave processing, which are used, for example, for millimeter wave radars. In these applications, the present invention may exert advantages which may attain a high added value from an industrial viewpoint.

It should be appreciated that the applicable scope of the present invention is limited neither to RF switches nor millimeter waves. Needless to say, the present invention may be applicable, for example, is to a mounting board for a semiconductor chip having a high-frequency circuit, for example, covering an operating bandwidth of frequency higher than the millimeter wave.

What is claimed is:

1. A semiconductor chip mounting board, comprising:
a plurality of input or output ports to be connected to a semiconductor chip for processing a high-frequency signal, the semiconductor chip having connecting terminals and side faces and having on top thereof a chip ground layer structured by a metal layer; and
an insulating substrate comprises:
a strip line formed on top of the insulating substrate and to be connected to the ports;
a cavity having a bottom face and an inner wall surface, or a recessed space with its upper end being open, for embedding the semiconductor chip therein;
a common ground made of metal and exposed to the bottom face of the cavity;
a coplanar line connected to the strip line;
triple parallel bonding wires connecting the connecting terminals of the semiconductor chip and the coplanar line; and
embedded conductors which are embedded at least in portions of an annular groove or annular gap defined between the inner wall surface of the cavity and the side faces of the semiconductor chip.

2. The semiconductor chip mounting board according to claim 1, wherein the embedded conductors are formed, being in non-contact with the chip ground layer.

3. The semiconductor chip mounting board according to claim 1, wherein:
the embedded conductors each have a columnar shape, stand on the common ground, have a head portion which is at substantially the same level as that of the chip ground layer, and are periodically arranged along the annular groove at a period ranging from 0.35 or more times to 0.70 or less times of the wavelength of a target high frequency annularly propagating through the annular groove.

4. The semiconductor chip mounting board according to claim 1, wherein
the semiconductor chip has a rectangular shape in plan; and
the embedded conductors each have a columnar shape, stand on the common ground, have a head portion which is at substantially the same level as that of the chip ground layer, and are arranged at least at four corners of the annular groove or in the vicinities of the four corners.

5. The semiconductor chip mounting board according to claim 1, wherein
the semiconductor chip has a square shape in plan; and
one side of the square shape has a length which is an integral multiple of one half of the wavelength of the target high frequency annularly propagating through the annular groove.

6. The semiconductor chip mounting board according to claim 1, wherein
the insulating substrate has a waveguide inside the wall surface of the cavity, the waveguide being made of a conductor and continuously provided circuiting along the wall surface.

7. The semiconductor chip mounting board, according to claim 1, wherein
the strip line is structured by a first signal strip conductor having an extended end portion, and formed on top of a dielectric substrate structuring the upper part of the insulating substrate;
the dielectric substrate has a ground conductor having a certain width and disposed under the first signal strip conductor, being stacked onto the rear face of the dielectric substrate;
the coplanar line comprises:
a second signal strip conductor which is formed on top of the dielectric substrate and connected to the first signal strip conductor, without being provided with the ground conductor immediately thereunder;
a pair of first ground strip conductors which are parallelly formed on the rear face of the dielectric substrate, being extended from the ground conductor so as to be located obliquely lateral sides of the extended end portion of the first signal strip conductor, or obliquely lateral sides of the second signal strip conductor; and
a pair of second ground strip conductors which are formed on the top of the dielectric substrate so as to be located obliquely lateral sides of the second signal strip conductor, and are connected to the pair of first ground strip conductors, respectively, through via holes formed in the dielectric substrate.

8. The semiconductor chip mounting substrate according to claim 1, wherein
the target high frequency is a millimeter wave; and
the semiconductor chip has an integrated circuit for processing the millimeter wave.

9. The semiconductor chip mounting board according to claim 2, wherein
the embedded conductors each have a columnar shape, stand on the common ground, have a head portion which is at substantially the same level as that of the chip ground layer, and are periodically arranged along the annular groove at a period ranging from 0.35 or more times to 0.70 or less times of the wavelength of a target high frequency annularly propagating through the annular groove.

10. The semiconductor chip mounting board according to claim 9, wherein
the semiconductor chip has a rectangular shape in plan; and
the embedded conductors each have a columnar shape, stand on the common ground, have a head portion which is at substantially the same level as that of the chip ground layer, and are arranged at least at four corners of the annular groove or in the vicinities of the four corners.

11. The semiconductor chip mounting board according to claim 10, wherein
the semiconductor chip has a square shape in plan; and
one side of the square shape has a length which is an integral multiple of one half of the wavelength of the target high frequency annularly propagating through the annular groove.

12. The semiconductor chip mounting board according to claim 11, wherein
the insulating substrate has a waveguide inside the wall surface of the cavity, the waveguide being made of a conductor and continuously provided circuiting along the wall surface.

13. The semiconductor chip mounting board, according to claim 12, wherein
the strip line is structured by a first signal strip conductor having an extended end portion, and formed on top of a dielectric substrate structuring the upper part of the insulating substrate;
the dielectric substrate has a ground conductor having a certain width and disposed under the first signal strip conductor, being stacked onto the rear face of the dielectric substrate;
the coplanar line comprises:
a second signal strip conductor which is formed on top of the dielectric substrate and connected to the first signal strip conductor, without being provided with the ground conductor immediately thereunder;
a pair of first ground strip conductors which are parallelly formed on the rear face of the dielectric substrate, being extended from the ground conductor so as to be located obliquely lateral sides of the extended end portion of the first signal strip conductor, or obliquely lateral sides of the second signal strip conductor; and
a pair of second ground strip conductors which are formed on the top of the dielectric substrate so as to be located obliquely lateral sides of the second signal strip conductor, and are connected to the pair of first ground strip conductors, respectively, through via holes formed in the dielectric substrate.

14. The semiconductor chip mounting substrate according to claim 13, wherein
the target high frequency is a millimeter wave; and
the semiconductor chip has an integrated circuit for processing the millimeter wave.

15. The semiconductor chip mounting board according to claim 3, wherein
the semiconductor chip has a rectangular shape in plan; and
the embedded conductors each have a columnar shape, stand on the common ground, have a head portion which is at substantially the same level as that of the chip ground layer, and are arranged at least at four corners of the annular groove or in the vicinities of the four corners.

16. The semiconductor chip mounting board according to claim 15, wherein
the semiconductor chip has a square shape in plan; and
one side of the square shape has a length which is an integral multiple of one half of the wavelength of the target high frequency annularly propagating through the annular groove.

17. The semiconductor chip mounting board according to claim 16, wherein
the insulating substrate has a waveguide inside the wall surface of the cavity, the waveguide being made of a conductor and continuously provided circuiting along the wall surface.

18. The semiconductor chip mounting board, according to claim 17, wherein
the strip line is structured by a first signal strip conductor having an extended end portion, and formed on top of a dielectric substrate structuring the upper part of the insulating substrate;
the dielectric substrate has a ground conductor having a certain width and disposed under the first signal strip conductor, being stacked onto the rear face of the dielectric substrate;
the coplanar line comprises:
a second signal strip conductor which is formed on top of the dielectric substrate and connected to the first signal strip conductor, without being provided with the ground conductor immediately thereunder;
a pair of first ground strip conductors which are parallelly formed on the rear face of the dielectric substrate, being extended from the ground conductor so as to be located obliquely lateral sides of the extended end portion of the first signal strip conductor, or obliquely lateral sides of the second signal strip conductor; and
a pair of second ground strip conductors which are formed on the top of the dielectric substrate so as to be located obliquely lateral sides of the second signal strip conductor, and are connected to the pair of first ground strip conductors, respectively, through via holes formed in the dielectric substrate.

19. The semiconductor chip mounting substrate according to claim 18, wherein
the target high frequency is a millimeter wave; and
the semiconductor chip has an integrated circuit for processing the millimeter wave.
